(19) United States
(12) Patent Application Publication
(10) Pub. No.: US 2012/0152353 A1
(43) Pub. Date: Jun. 21, 2012

(54) SOLAR CELL AND METHOD FOR MAKING THE SAME

(75) Inventors: ZHEN-DONG ZHU, Beijing (CN); QUN-QING LI, Beijing (CN); SHOU-SHAN FAN, Beijing (CN)

(73) Assignees: HON HAI PRECISION INDUSTRY CO., LTD., Tu-Cheng (TW); TSINGHUA UNIVERSITY, Beijing (CN)

(21) Appl. No.: 13/286,892

(22) Filed: Nov. 1, 2011

(30) Foreign Application Priority Data
Dec. 15, 2010 (CN) 201010589786.7

(51) Int. Cl. H01L 31/0236; H01L 31/18; H01L 31/0264

(52) U.S. Cl. 136/261; 438/98; 257/E31.124

(57) ABSTRACT

A solar cell is provided. The solar cell includes a silicon substrate, a back electrode, a doped silicon layer, and an upper electrode. The silicon substrate includes a lower surface, an upper surface opposite to the lower surface, and a plurality of three-dimensional nano-structures located on the upper surface. Each three-dimensional nano-structure has a stepped structure. The back electrode is located on and electrically connected to the lower surface of the silicon substrate. The doped silicon layer is attached to the three-dimensional nano-structures and the upper surface of the silicon substrate between the three-dimensional nano-structures. The upper electrode is located on at least part of the doped silicon layer. A method for making the solar cell is also provided.

### RELATED APPLICATIONS

This application claims all benefits accruing under 35 U.S.C. §119 from China Patent Application No. 201010589786.7, filed on Dec. 15, 2010 in the China Intellectual Property Office, the disclosure of which is incorporated herein by reference.

### BACKGROUND

1. Technical Field

The present disclosure relates to a solar cell and a method for making the same.

2. Discussion of Related Art

Solar cells can convert light energy into electrical energy. Solar cells work via photovoltaic effects of the semiconductor materials. Solar cells can be silicon solar cells, gallium arsenide solar cells, or organic thin film solar cells. Among the solar cells, silicon solar cells are most widely fabricated because of their excellent efficiency in energy conversion and low production cost.

A silicon solar cell generally includes a back electrode, a silicon substrate, a doped silicon layer and an upper electrode disposed in that sequence. The doped silicon layer is used as a photovoltaic conversion material, and has a smooth surface for extracting sunlight. The silicon substrate and the doped silicon layer can form a number of P-N junctions, the P-N junctions can produce a number of electron-hole pairs under excitation of the sunlight. However, the area of the smooth surface for extracting sunlight is small, thus an extraction light surface of the solar cell has a small area. Furthermore, when the sunlight irradiates the smooth surface, a part of the sunlight is absorbed by the doped silicon layer, and the other part of the light reflected back by the smooth surface can not be reused. Therefore, the utilization efficiency of the solar cell is relatively low.

What is needed, therefore, is to provide a solar cell with a relatively large extraction light surface, and a method for making the same.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic view of one embodiment of a solar cell including a silicon substrate.

FIG. 2 is a schematic view of the silicon substrate shown in FIG. 1.

FIG. 3 shows a Scanning Electron Microscope (SEM) image of the silicon substrate shown in FIG. 1.

FIG. 4 shows a flowchart of one embodiment of a method for making the solar cell shown in FIG. 1.

FIG. 5 shows a process flowchart of one embodiment of a method for forming a number of three-dimensional nano-structures on a surface of the silicon substrate.

FIG. 6 shows an SEM image of one embodiment of a number of closely packed hexagonally monolayer nanospheres formed on a second surface of the silicon substrate.

FIG. 7 shows an SEM image of one embodiment of a number of packed monolayer simple cubic nanospheres formed on a second surface of the silicon substrate.

FIG. 8 is a schematic view of one embodiment of a solar cell.

FIG. 9 is a schematic view of another embodiment of a solar cell including a silicon substrate.

FIG. 10 is a schematic view of the silicon substrate shown in FIG. 9.

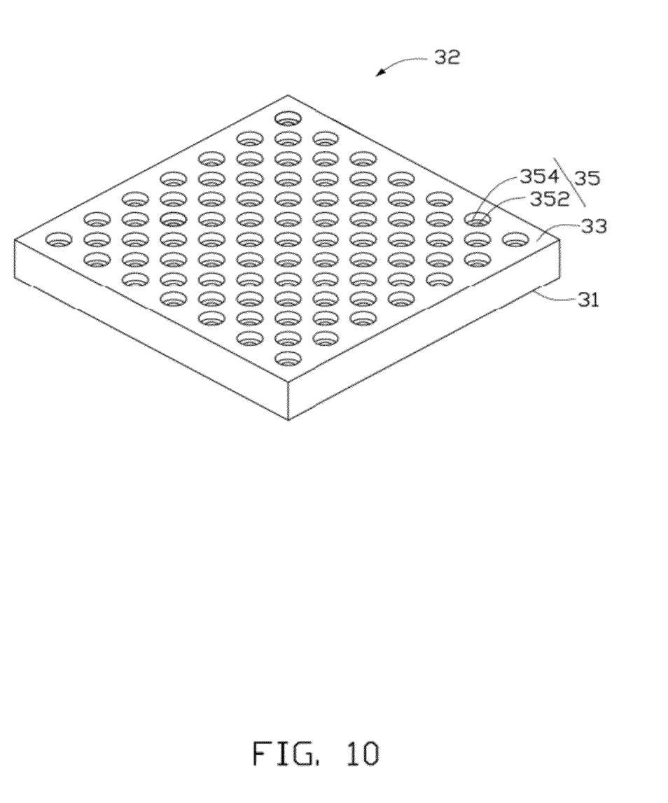

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

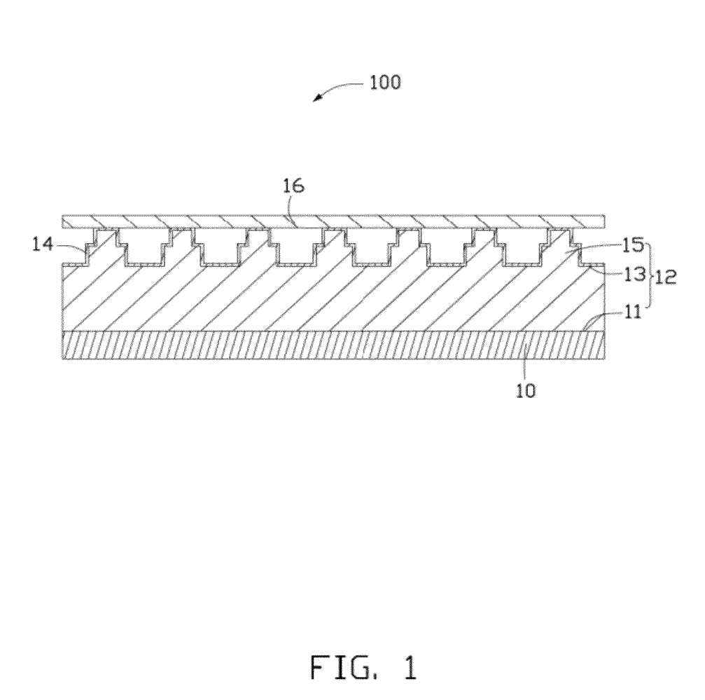

Referring to FIG. 1, one embodiment of a solar cell 100 is provided. The solar cell 100 includes a back electrode 10, a silicon substrate 12, a doped silicon layer 14 and an upper electrode 16 disposed in that order. The upper electrode 16 includes an upper surface 162 for receiving sunlight. The silicon substrate 12 includes a lower surface 11, an upper surface 13 opposite to the lower surface 11, and a number of three-dimensional nano-structures 15 located on the upper surface 13. The upper surface 13 is adjacent to the upper electrode 16. Each three-dimensional nano-structure 15 has a stepped structure. The back electrode 10 is located on and electrically connected to the lower surface 11 of the silicon substrate 12. The doped silicon layer 14 is attached on the three-dimensional nano-structures 15 and the upper surface 13 between the three-dimensional nano-structures 15. The upper electrode 16 is located on at least a part surface of the doped silicon layer 14.

The back electrode 10 can be made of silver, aluminum or magnesium. A thickness of the back electrode 10 ranges from about 10 micrometers to about 300 micrometers. In one embodiment, the back electrode 10 is an aluminum foil with a thickness of about 200 micrometers.

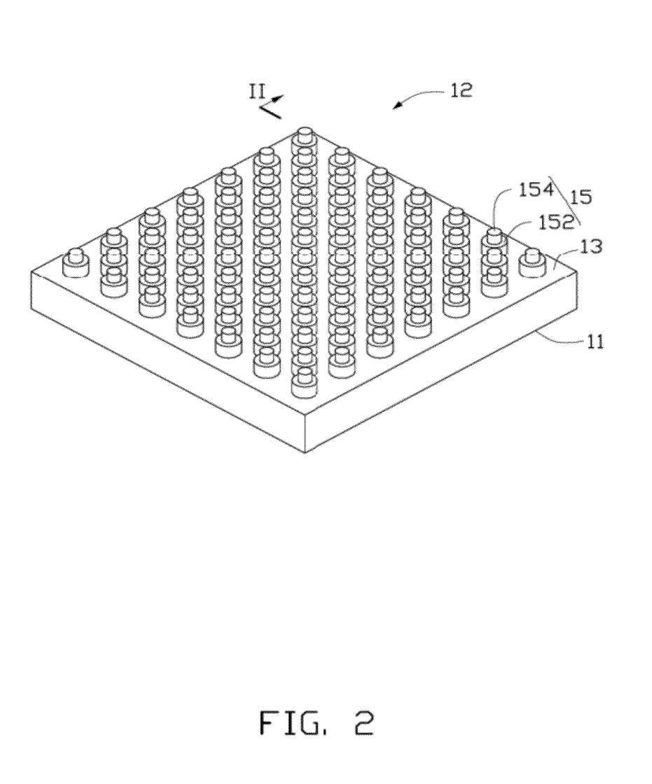

Referring to FIG. 2, the silicon substrate 12 can be a P-type silicon substrate. A material of the silicon substrate 12 can be single crystal silicon, multiple crystal silicon and other P-type semiconductor material. In one embodiment, the silicon substrate 12 is single crystal silicon. A thickness of the silicon substrate 12 ranges from about 200 micrometers to about 300 micrometers.

The three-dimensional nano-structures 15 can be separately arranged on the upper surface 13 of the silicon substrate 12 in form of an array. The three-dimensional nano-structures 15 in the array can be simple cubicly arranged, close hexagonally arranged, or concentric circularly arranged. The three-dimensional nano-structures 15 can be arranged to form a single pattern or a pattern group. The single pattern can be a triangle, parallelogram, diamond, square, trapezoid, rectangle, or circle. Adjacent three-dimensional nano-structures 15 are substantially equidistantly arranged. A distance between adjacent three-dimensional nano-structures 15 ranges from about 10 nanometers to about 1000 nanometers. The arrangement of the three-dimensional nano-structures 15 and the distance between adjacent three-dimensional nano-structures 15 can be selected as desired. In one embodiment, the three-dimensional nano-structures 15 are hexagonally close-packed to form a single square pattern, and the distance between adjacent three-dimensional nano-structures 15 is about 30 nanometers.

The three-dimensional nano-structures 15 can be a number of stepped bulges. The stepped bulge is a stepped body protruding from the upper surface 13 of the silicon substrate 12. The stepped bulge can be a multi-layer structure such as a multi-layer prism, a multi-layer frustum of a cone, or a multi-layer cylinder. In one embodiment, the three-dimensional nano-structure 15 is a stepped cylindrical structure. The maximum size of the three-dimensional nano-structure 15 is less than or equal to 1000 nanometers, namely, the length, the width, and the height are less than or equal to 1000 nanometers. In one embodiment, the length, the width, and the height of the three-dimensional nano-structure 15 are in a range from about 10 nanometers to about 500 nanometers.

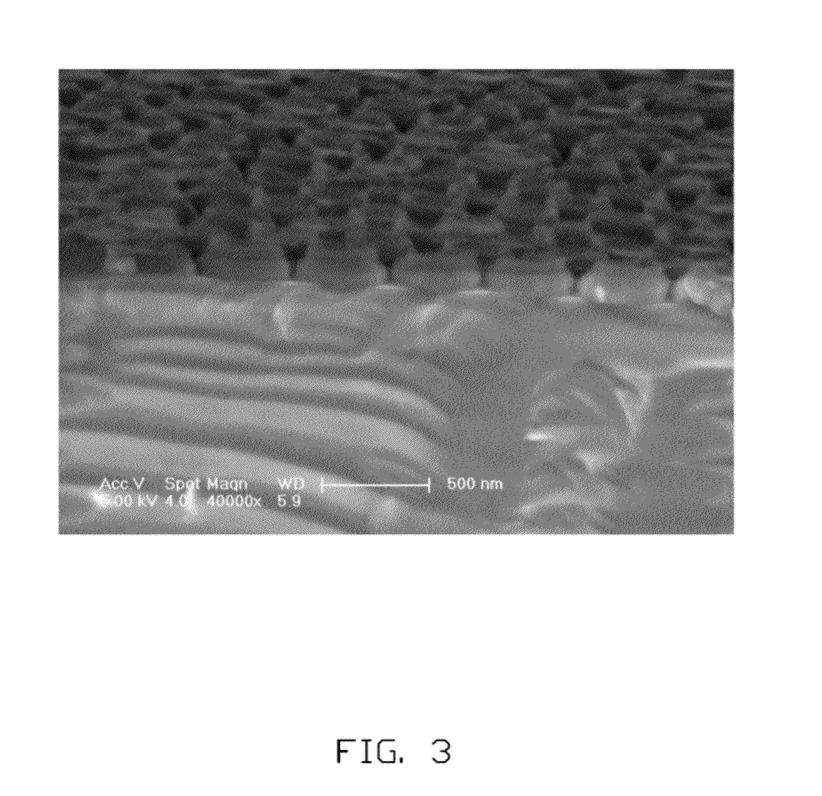

Referring to FIGS. 2 and 3, in one embodiment, the three-dimensional nano-structure 15 is a two-layer cylindrical structure including a first cylinder 152 and a second cylinder 154 extending from a top surface of the first cylinder 152. The diameter of the second cylinder 154 is less than the diameter of first cylinder 152 to form the stepped structure. The first cylinder 152 is adjacent to the lower surface 11 of the silicon substrate 12 than the second cylinder 154. The first cylinder 152 extends substantially perpendicularly and upwardly from the upper surface 13. The second cylinder 154 extends substantially perpendicularly and upwardly from the top surface of the first cylinder 152. In one embodiment, the second cylinder 154 and the first cylinder 152 are coaxial. The second cylinder 154 and the first cylinder 152 are an integral structure.

In one embodiment, the diameter of the first cylinder 152 can be in a range from about 30 nanometers to about 1000 nanometers. A height of the first cylinder 152 can be in a range from about 50 nanometers to about 1000 nanometers. The diameter of the second cylinder 154 can be in a range from about 10 nanometers to about 500 nanometers. A height of the second cylinder 154 can be in a range from about 20 nanometers to about 500 nanometers. A distance between adjacent first cylinders 152 can be in a range from about 10 nanometers to about 1000 nanometers.

In one embodiment, the diameter of the first cylinder 152 can be in a range from about 50 nanometers to about 200 nanometers. A height of the first cylinder 152 can be in a range from about 100 nanometers to about 500 nanometers. The diameter of the second cylinder 154 can be in a range from about 20 nanometers to about 200 nanometers. A height of the second cylinder 154 can be in a range from about 100 nanometers to about 300 nanometers. A distance between adjacent first cylinders 152 can be in a range from about 10 nanometers to about 30 nanometers. Thus, both the first cylinders 152 and the second cylinders 154 can contribute to extract the sunlight.

In one embodiment, the diameter of the first cylinder 152 is about 380 nanometers, the height of the first cylinder 152 is about 105 nanometers. The diameter of the second cylinder 154 is about 280 nanometers. The height of the second cylinder 154 is about 55 nanometers. The distance between two adjacent first cylinders 152 is about 30 nanometers.

The doped silicon layer 14 is located around an outer surface of the three-dimensional nano-structures 15 and the upper surface 13 between adjacent three-dimensional nano-structures 15. The doped silicon layer 14 is an N-type doped silicon layer. A thickness of the N-type doped silicon layer approximately ranges from 500 nanometers to 1 micrometer. The doped silicon layer 14 can be formed by injecting superfluous N-type doped material, such as phosphorus or arsenic, into the upper surface 13 of the silicon substrate 12. An interface between the doped silicon layer 14 and the silicon substrate 12 forms a plurality of P-N junctions that can be used to convert solar energy to electrical energy. It can be understood that the three-dimensional nano-structures 15 have photonic crystal property; and the three-dimensional nano-structures 15 are located on the upper surface 13 of the silicon substrate 12, which makes the upper surface 13 have a large area, further than making the interface forming the P-N junctions have a large area. Thus the solar cell 100 can have a large extraction light surface. Therefore, it can increase the photons residence time in the interface and broaden the frequency range of light absorbed by the three-dimensional nano-structures, thus, the light absorbing efficiency of the solar cell 100 is improved. Furthermore the photoelectric conversion efficiency of the solar cell 100 is also improved.

In addition, if the sunlight irradiates on side surfaces of the first cylinder 152 and the second cylinder 154, a part of the sunlight is absorbed by the first cylinder 152 and the second cylinder 154, another part of the sunlight is reflected by the first cylinder 152 and the second cylinder 154. The sunlight reflected by the first cylinder 152 and the second cylinder 154 can mostly re-irradiate on the adjacent three-dimensional nano-structures 15, and can be absorbed and reflected by the adjacent three-dimensional nano-structures 15. Therefore, the sunlight irradiating on the three-dimensional nano-structures 15 can be many times reflected and absorbed in the three-dimensional nano-structures 15. Namely, if the sunlight irradiates on the sides of the first cylinder 152 and the second cylinder 154 for the first time, the sunlight can be mostly used, thus the light utilization rate of the solar cell 100 can be further improved.

In one embodiment, a part of the upper electrode 16 can directly contact with the doped silicon layer 14, and the other part of the upper electrode 16 is suspended over the doped silicon layer 14 between adjacent three-dimensional nano-structures 15. In one embodiment, the upper electrode 16 is directly coated on the doped silicon layer 14, and completely contacted with the doped silicon layer 14.

The upper electrode 16 is used to collect current produced by the photoelectric conversion in the P-N junctions. The upper electrode 16 has a good transparency and conductivity to make the solar cell 100 have high photoelectric conversion efficiency, good endurance, and uniform resistance. As such, the upper electrode 16 improves the property of the solar cell 100. The upper electrode 16 is an indium tin oxide layer, the indium tin oxide layer is uniformly coated on the doped silicon layer 14, and contacts with the doped silicon layer 14. In other embodiments, the upper electrode 16 can be a carbon nanotube structure composed of a number of carbon nanotubes. The carbon nanotube structure is a freestanding structure without any supporter. The carbon nanotube structure can be at least one carbon nanotube film or at least one carbon nanotube wire. The carbon nanotube structure can be partly suspended and partly contact with the doped silicon layer 14 by the three-dimensional nano-structures 15. In one embodiment, the upper electrode 16 is a layer of carbon nanotube film being free standing. The carbon nanotube film is partly suspended and partly contacts with the doped silicon layer 14.

The solar cell 100 can further include an intrinsic layer (not shown). The intrinsic layer is located between the silicon substrate 12 and the doped silicon layer 14. The intrinsic layer is made of silicon dioxide (SiO₂) or silicon nitride (Si₃N₄) as an insulating layer. A thickness of the intrinsic layer is about 1 angstrom to about 30 angstrom. The intrinsic layer is configured to lower the speed of recombination of electron-hole pairs, and further improve the photoelectric conversion efficiency of the solar cell 100.

At the interface of the silicon substrate 12 and the doped silicon layer 14, redundant electrons in the doped silicon layer 14 can tend toward the silicon substrate 12, and form an inner electrical field. The orientation of the inner electrical field is from the doped silicon layer 14 to the silicon substrate 12. When the sunlight irradiates the upper electrode 16, a number of electron-hole pairs are produced by the P-N junctions. The electron-hole pairs are separated under the inner electrical field. The electrons in the doped silicon layer 14 move towards the upper electrode 16 and are collected by the upper electrode 16. The holes in the silicon substrate 12 move towards the back electrode 10 and are collected by the back electrode 10. Thus an electric current is formed and goes through an electric circuit outside of the solar cell 100.

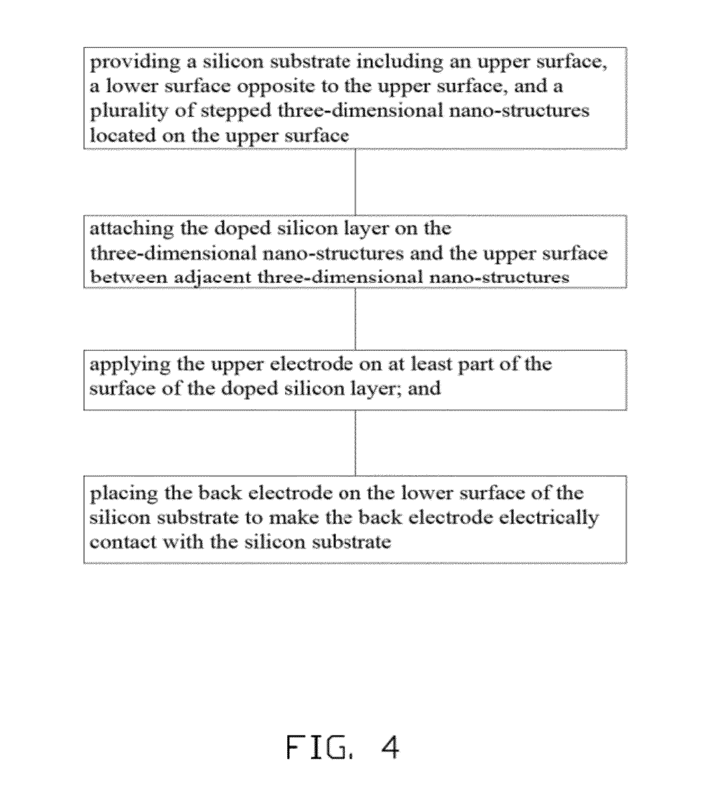

Referring to FIGS. 1-2, 4 and 5, one embodiment of a method for making the solar cell 100 is provided. The method includes the following steps:

S10, providing a silicon substrate 12 including an upper surface 13, a lower surface 11 opposite to the upper surface 13, and a plurality of stepped three-dimensional nano-structures 15 located on the upper surface 13;

S11, attaching the doped silicon layer 14 on the three-dimensional nano-structures 15 and the upper surface 13 between adjacent three-dimensional nano-structures 15;

S12, applying the upper electrode 16 on at least part of the surface of the doped silicon layer 14; and

S13, placing the back electrode 10 on the lower surface 11 of the silicon substrate 12 to make the back electrode 10 electrically contact with the silicon substrate 12.

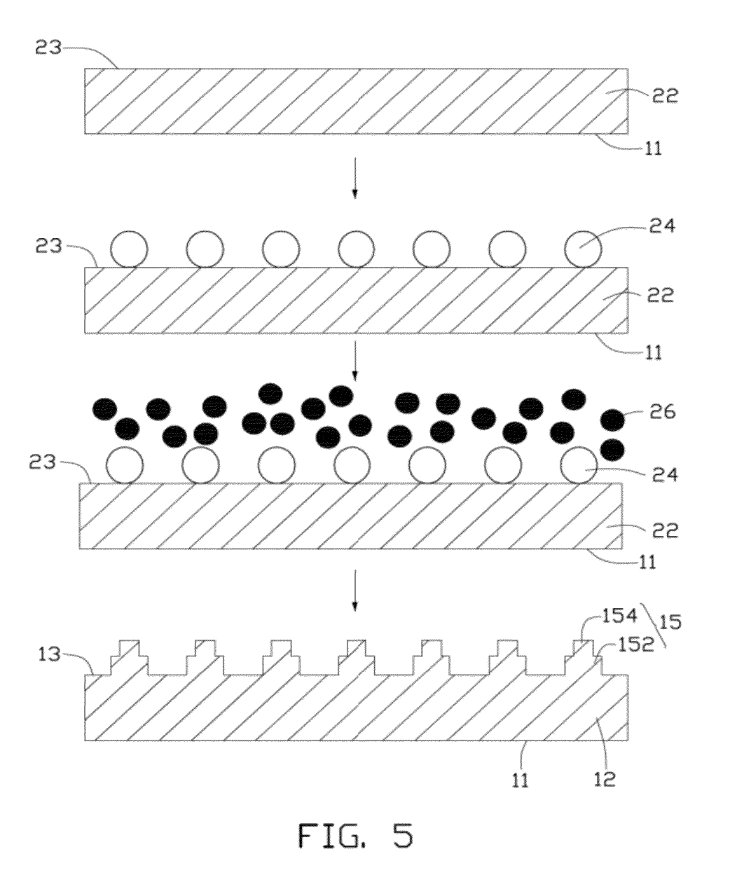

Referring to FIG. 5, the step S10 can include the following steps:

S101, providing a silicon plate 22 having the lower surface 11 and an upper surface 23 opposite to the lower surface 11;

S102, forming a mask layer 24 on the upper surface 23 of the silicon plate 22;

S103, etching the upper surface 23 of the silicon plate 22 and the mask layer 24 by a reacting atmosphere 26, to form a plurality of stepped three-dimensional nano-structures 15; and

S104, removing the mask layer 24, thereby acquiring the silicon substrate having a number of three-dimensional nano-structures.

In step S101, the silicon plate 22 is a P-type semiconductor. A material of the P-type semiconductor can be single crystal silicon, multiple crystal silicon, or other P-type semiconductor materials. In one embodiment, the silicon plate 22 is a P-type single crystal silicon sheet. A thickness of the silicon plate 22 can range from about 200 micrometers to about 300 micrometers. A size and the thickness of the silicon plate 22 can be selected by desired.

In the step S101, the upper surface 23 of the silicon plate 22 can be further hydrophilicly treated. Specifically, the upper surface 23 is cleaned by a standard cleaning process used in room cleaning. The silicon plate 22 is soaked in a hydrophilic solution under a temperature ranging from about 30 centigrade degrees to about 100 centigrade degrees, for about 30 minutes to about 60 minutes. Then, the silicon plate 22 is rinsed by deionized water for about two or third times. Finally, the upper surface 23 of the silicon plate 22 is dried by nitrogen gas. Wherein, the hydrophilic solution can be a mixture of NH₃.H₂O, H₂O₂, and H₂O. A volume ratio NH₃.H₂O:H₂O₂:H₂=x:y:z.; x can range from about 0.2 to about 2, y can be in a range from about 0.2 to 2, z can range from about 1 to about 20.

Step S102 can include forming monolayer nanospheres on the upper surface 23 of the silicon plate 22. The monolayer nanospheres can be used as the mask layer 24. The stepped bulge structures can be formed at the monolayer nanospheres. Specifically, the step S102 can include the substeps of:

S1021, preparing a nanosphere solution including a number of nanospheres;

S1022, forming a monolayer nanosphere solution on the upper surface 23 of the silicon plate 22, wherein the number of nanospheres is arranged on the upper surface 23 in form of an array; and

S1023, drying the monolayer nanosphere solution.

In step S1021, the diameter of the nanosphere can be in range from about 60 nanometers to about 500 nanometers, such as 100 nanometers, 200 nanometers, 300 nanometers, or 400 nanometers. The material of the nanosphere can be polymer or silicon. The polymer can be polymethyl methacrylate (PMMA) or polystyrene (PS). In one embodiment, a PS nanosphere solution can be synthesized by emulsion polymerization.

In one embodiment, in the step S1021, about 150 milliliters water, about 3 microliters to about 5 microliters nanosphere solution having a weight percentage of about 0.01% to about 10%, and an SDS solution having a weight percentage of about 0.01% to about 3%, are added into a container in sequence to form a mixture. The mixture can be kept for about 30 minutes to about 60 minutes. In addition, about 1 microlitre to about 3 microlitres SDS having a weight percentage of about 4% can be added in the mixture to adjust the surface tension of the nanospheres. In one embodiment, the container is a watch glass with a diameter of about 15 centimeters.

In step S1022, the monolayer nanosphere solution can be formed on the silicon plate 22 by a Czochralski method or a spinning coating method.

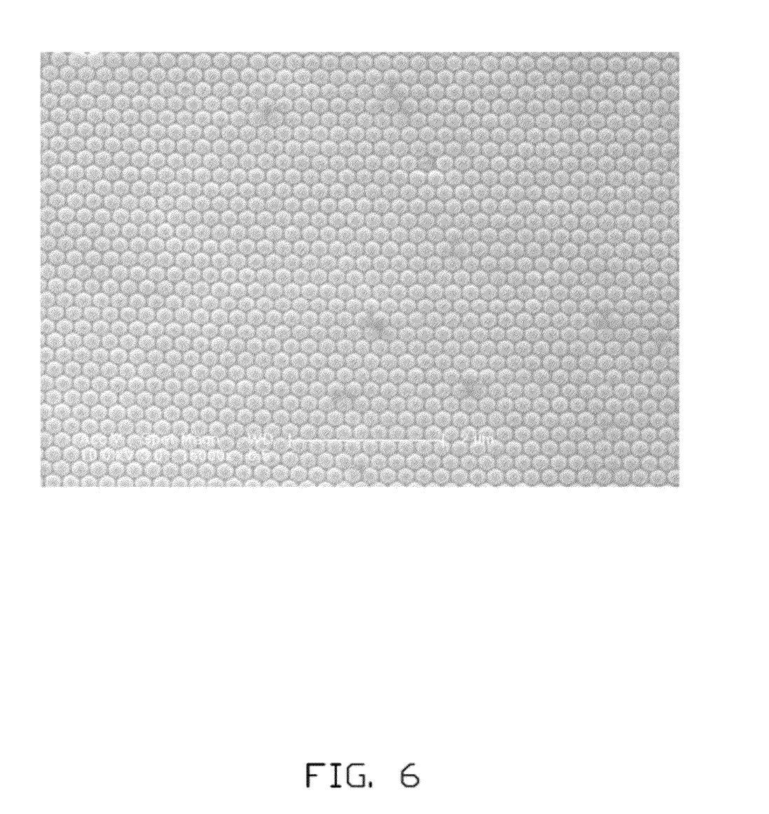

In one embodiment, the monolayer nanosphere solution is formed by the Czochralski method. Specifically, the silicon plate 22 is inserted into the nanosphere solution prepared by the step S1021 slowly and obliquely along a sidewall of the watch glass; and then the silicon plate 22 is drawn out of the nanosphere solution receiving in the watch glass slowly. Wherein, an angle between the upper surface 23 of the silicon plate 22 and the vertical direction can be in a range from about 5 degrees to about 15 degrees. The speed of inserting and drawing the silicon plate 22 can be in a range from about 3 millimeters per hour to about 10 millimeters per hour. In one embodiment, the angle between the upper surface 23 of the silicon plate 22 and the vertical direction is about 9 degrees, and the speed of inserting and drawing the silicon plate 22 is about 5 millimeters per hour. During the process of inserting and drawing the silicon plate 22, the nanospheres in the nanosphere solution are self-assembled into a number of close-packed hexagonally monolayer nanospheres as shown in FIG. 6.

In one embodiment, the monolayer nanosphere solution is formed by the spinning coating method. Specifically, the silicon plate 22 hydrophilicy treated is soaked in a sodium dodecyl sulfate solution (SDS) having a weight percentage of about 2% to about 5% about for about 2 hours to about 24 hours. The silicon plate 22 is taken out, and about 3 microliters to about 5 microliters PS is coated on the upper surface 23 of the silicon plate 22. Then, the silicon plate 22 is spun at a speed from about 400 revolutions per minute to about 500 revolutions per minute for about 5 seconds to about 30 seconds. The spinning speed of the silicon plate 22 is further increased to a range from about 800 revolutions per minute to about 1000 revolutions per minute and is maintained for about 30 seconds to about 2 minutes. Then, the spinning speed of the silicon plate 22 is again improved to a range from about 1400 revolutions per minute to about 1500 revolutions per minute and is maintained for about 10 seconds to about 20 seconds. Finally, the upper surface 23 with the nanospheres dispersed thereon is dried, to form a number of hexagonally close-packed monolayer nanospheres, thereby forming the mask layer 24. Further, the mask layer 24 is baked at a temperature of about 50 centigrade degrees to about 100 centigrade degrees, for about 1 minute to about 5 minutes.

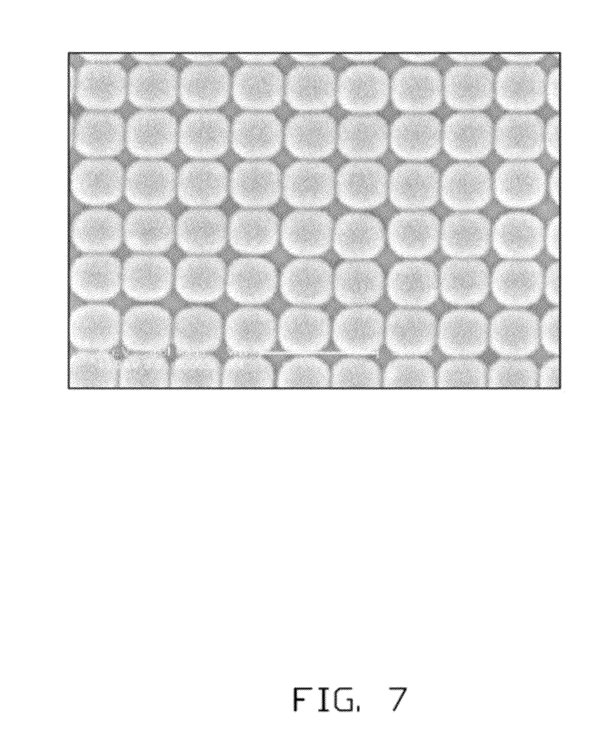

It can be noted that the surface tension of the nanosphere solution can be controlled, to form the monolayer nanospheres squarely close-packed as shown in FIG. 7 on the upper surface 13 of the silicon substrate 12.

In one embodiment, step (c) can be carried out in a microwave plasma system at Reaction-Ion-Etching mode. The microwave plasma system produces the reactive atmosphere 26. The reactive atmosphere 26 with lower ions energy diffuses to a surface of the monolayer nanospheres being used as the mask layer 24. The reactive atmosphere 26 can etch the mask layer 24 and simultaneously etch the silicon plate 22 by the mask layer 24. The nanospheres become smaller and the gap between the adjacent nanospheres becomes greater during the process. As the gap between the adjacent nanospheres increases, more portions of the silicon plate 22 can be etched. Specifically, the upper surface 23 between the nanospheres is etched to form a number of first cylinders 152; simultaneously, the nanospheres located on the upper surface 23 are etched to form a number of nanospheres with smaller diameters than the diameters of the cylinders 152. The first cylinder 152 can be further etched to form the second cylinder 154. Thus, the three-dimensional nano-structures 15 with the stepped structure are obtained.

In one embodiment, the reactive atmosphere 26 consists of chlorine gas (Cl₂), argon gas (Ar), and oxygen gas (O₂). The input flow rate of the chlorine gas can be in a range from about 10 standard-state cubic centimeters per minute to about 60 standard-state cubic centimeters per minute. The input flow rate of the argon gas can be in a range from about 4 standard-state cubic centimeters per minute to about 20 standard-state cubic centimeters per minute. The input flow rate of the oxygen gas can be in a range from about 4 standard-state cubic centimeters per minute to about 20 standard-state cubic centimeters per minute. The power of the plasma system can be in a range from about 40 Watts to about 70 Watts. The working pressure of the reactive atmosphere 26 can be a range from about 2 Pa to about 10 Pa. The tailoring and etching time in the reactive atmosphere 26 can be in a range from about 1 minute to about 2.5 minutes. The ratio between the power of the plasma system and the working pressure of the reactive atmosphere 110 can be less than 20:1. In one embodiment, the ratio between the power of the plasma system and the working pressure of the reactive atmosphere 26 is less than 10:1. The distance between the two adjacent three-dimensional nano-structures 15 can be determined by the etching time.

Furthermore, an adjusting gas can be added into the reactive atmosphere 26 to adjust the etching time. The adjusting gas can be boron trichloride (BCl₃), carbon tetrafluoride (CF₄), sulfur hexafluoride (SF₆), trifluoromethane (CHF₃), or combination thereof. The input flow rate of the adjusting gas can be in a range from about 20 standard-state cubic centimeters per minute to about 40 standard-state cubic centimeters per minute.

In step S104, the mask layer 24 can be removed by dissolving in a stripping agent such as tetrahydrofuran (THF), acetone, butanone, cyclohexane, hexane, methanol, or ethanol. The mask layer 24 can also be removed by peeling with an adhesive tape. The three-dimensional nano-structures 15 cannot be removed and will be retained. Therefore, the silicon plate 22 can form the silicon substrate 12, the upper surface 23 of the silicon plate 22 can form the upper surface 13 of the silicon substrate 12. In one embodiment, the three-dimensional nano-structures 15 have structures shown in FIG. 2.

In one embodiment, the step S12 can further include a step of applying an intrinsic layer on the three-dimensional nano-structures 15 and the upper surface 13 of the silicon substrate 12, before forming the doped silicon layer 14.

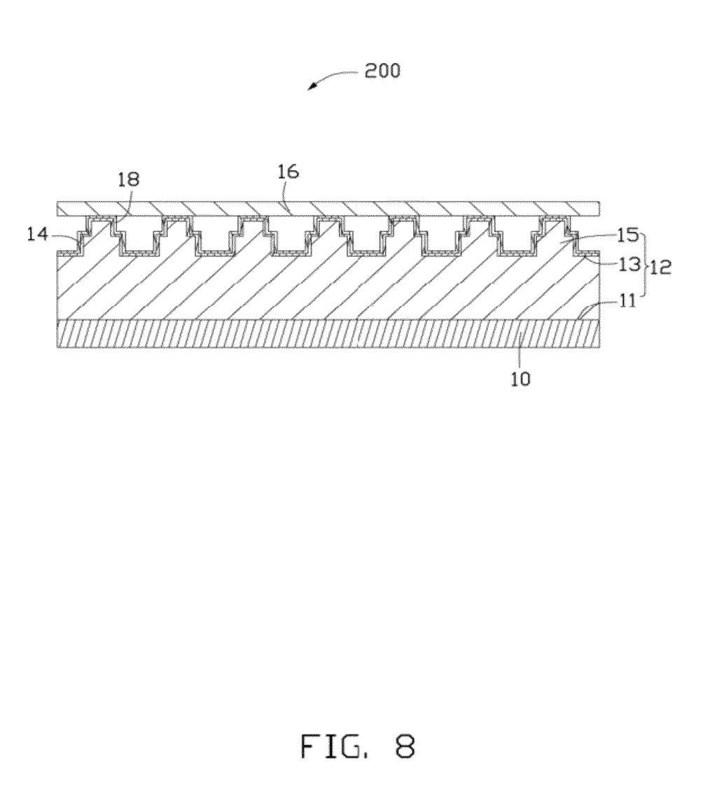

Referring to FIG. 8, one embodiment of a solar cell 200 is provided. The solar cell 200 further includes a metal layer 18 attached on an outer surface of the doped silicon layer 14. The metal layer 18 can be partly or completely contact with the upper electrode 16. In one embodiment, the upper electrode 16 between adjacent three-dimensional nano-structures 15 is suspended, and the other part of the upper electrode 16 contact with the metal layer 18. The metal layer 18 can be a single layer sheet-structure or a multi-layer sheet-structure, which is formed by a number of nano-scaled metal particles spread out on the doped silicon layer 14. A thickness of the metal layer 18 ranges from about 2 nanometers to about 200 nanometers. A material of the metal layer 18 can be gold, silver, copper, iron or aluminum. In one embodiment, the metal layer 18 can be a nano-gold layer with a thickness of about 50 nanometers.

The doped silicon layer 14 is coated with the metal layer 18, when the sunlight goes through the upper electrode 16 and irradiated on the metal layer 18, a surface of the metal layer 18 is excited to form a number of plasmas, therefore, the photon absorption of the doped silicon layer 14 adjacent to the metal layer 18 is improved. In addition, electromagnetic field produced by the plasmas on the surface of the metal layer 18, can be conductive to separate the electron-hole pairs produced in the P-N junctions, under the sunlight.

Other characteristics of the solar cell 200 are the same as the solar cell 100 disclosed above.

One embodiment of a method for making the solar cell 200 is provided. The method for making the solar cell 200 can further include a step of forming the metal layer 18 on the outer surface of the doped silicon layer 14. In one embodiment, the metal layer 18 is formed on the outer surface of the doped silicon layer 14 by an electron beam evaporation method. Other characteristics of the method for making the solar cell 200 are the same as the method for making the solar cell 100 disclosed above.

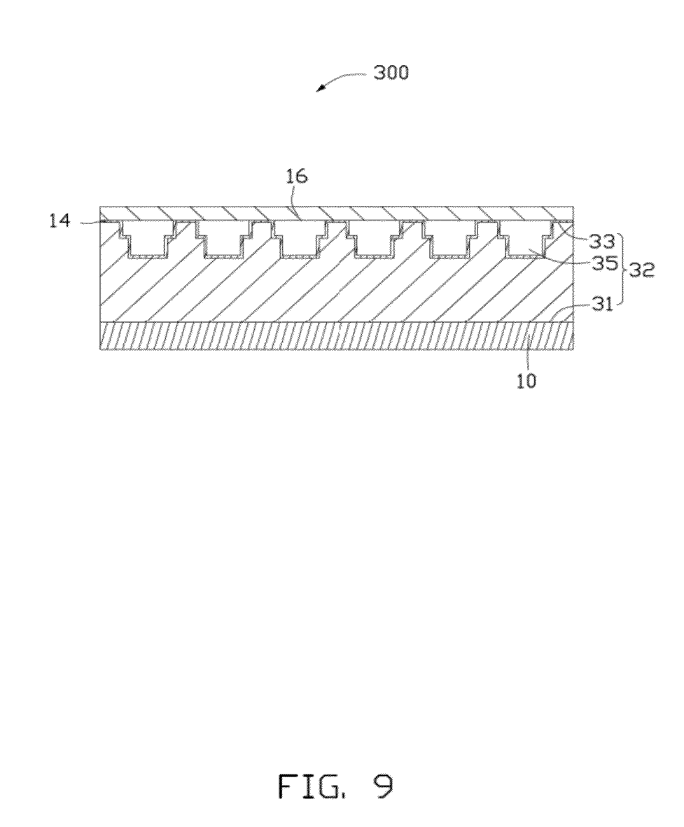

Referring to FIG. 9, one embodiment of a solar cell 300 is provided. The solar cell 300 can include the back electrode 10, a silicon substrate 32, the doped silicon layer 14, and an upper electrode 16, in sequence. The silicon substrate 32 includes a lower surface 31 and an upper surface 33 opposite to the lower surface 31. The silicon substrate 32 defines a number of three-dimensional nano-structures 35 adjacent to the upper surface 33. Each three-dimensional nano-structure 35 has a hollow stepped structure.

The structure of the solar cell 300 is substantially similar to that of the solar cell 100 described above, except that the three-dimensional nano-structures 35 are inverted and defined in the silicon substrate 32. Each three-dimensional nano-structure 35 is a blind hole caved in the silicon substrate 32 from the upper surface 33 of the silicon substrate 32. The shape of the three-dimensional nano-structure 35 can be a multi-layer structure such as a multi-layer frustum of a prism, a multi-layer frustum of a cone, or a multi-layer cylinder. In one embodiment, the shape of the three-dimensional nano-structure 35 is a two-layer cylindrical structure including a first cylindrical space 352 and a second cylindrical space 354 substantially coaxially aligned with the first cylindrical space 352. The first cylindrical space 352 is adjacent to the lower surface 31 of the silicon substrate 32. The diameter of the second cylindrical space 354 is greater than the diameter of first cylindrical space 352. The first cylindrical spaces 352 can be considered a first nano-structure array and the second cylindrical spaces 354 could be considered another nano-structure array formed on top of the first nano-structure array.

It can be understood that other characteristics of the solar cell 300 are the same as that of the solar cell 100 described above.

It also can be understood that the solar cell 300 can further include a metal layer (not shown) located on the doped silicon layer 34. The thickness and the material of the metal layer are the same as those of the metal layer 18 of the solar cell 200 described above.

One embodiment of a method for making the solar cell 300 is provided. Because the three-dimensional nano-structures 35 are stepped blind holes, a step of forming a mask defining a number of holes on the upper surface 23 of the silicon plate 22 is provided. Wherein, the mask is a film defining the through holes arranged in the form of array, and is not separated into several pieces. The mask can be made of polymer such as poly ethylene terephthalate (PET), polycarbonate (PC), polyethylene (PE), or polyimide (PI). The mask can be formed by nano-imprint or template deposition.

It can be understood that when the continuous film defining the through holes is used as the mask, the upper surface 23 of the silicon plate 22 corresponding to the through holes is etched by the reactive atmosphere 26 to define the first cylindrical spaces 352. Simultaneously, the mask is also etched by the reactive atmosphere 26 to increase the diameters of the through holes, thus the scopes of the upper surface 23 corresponding to the through holes are enlarged, therefore, the etching areas of the upper surface 23 of the silicon plate 22 is enlarged, thereby forming the second cylindrical spaces 354. So, the three-dimensional nano-structures 35 are obtained in the silicon plate 22 corresponding to the through holes of the mask.

Other characteristics of the method for making the solar cell 300 are the same as the method for making the solar cell 100 disclosed above.

It is to be understood that the above-described embodiment is intended to illustrate rather than limit the disclosure. Variations may be made to the embodiment without departing from the spirit of the disclosure as claimed. The above-described embodiments are intended to illustrate the scope of the disclosure and not restricted to the scope of the disclosure.

It is also to be understood that the above description and the claims drawn to a method may include some indication in reference to certain steps. However, the indication used is only to be viewed for identification purposes and not as a suggestion as to an order for the steps.

What is claimed is:

1. A solar cell, comprising:
a silicon substrate comprising a lower surface, an upper surface, and a plurality of three-dimensional nano-structures located on the upper surface, each three-dimensional nano-structure having a stepped structure;
a back electrode located on and electrically connected to the lower surface of the silicon substrate;
a doped silicon layer attached to the plurality of three-dimensional nano-structures and the upper surface of the silicon substrate between the plurality of three-dimensional nano-structures; and
an upper electrode located on at least part of the doped silicon layer.

2. The solar cell of claim 1, wherein the stepped structure is a multi-layer prism, a multi-layer frustum of a cone, or a multi-layer cylinder.

3. The solar cell of claim 1, wherein the stepped structure of each three-dimensional nano-structure protrudes from the upper surface of the silicon substrate.

4. The solar cell of claim 3, wherein the plurality of three-dimensional structure comprises a first cylinder adjacent to the lower surface of the silicon substrate and a second cylinder located on the first cylinder, a diameter of the first cylinder is greater than a diameter of the second cylinder.

5. The solar cell of claim 4, wherein the first cylinder and the second cylinder are coaxial and an integrated structure, the second cylinder extends substantially perpendicularly and upwardly from a top surface of the first cylinder.

6. The solar cell of claim 4, wherein the diameter of the first cylinder is in a range from about 50 nanometers to about 1000 nanometers, a height of the first cylinder is in a range from about 100 nanometers to about 1000 nanometers, the diameter of the second cylinder is in a range from about 10 nanometers to about 500 nanometers, a height of the second cylinder is in a range from about 20 nanometers to about 500 nanometers.

7. The solar cell of claim 1, wherein the stepped structure of each three-dimensional nano-structure is a stepped blind hole defined in the upper surface of the silicon substrate.

8. The solar cell of claim 7, wherein each of the plurality of the three-dimensional structures is an indentation in the upper surface, and comprises a first cylinder space adjacent to the lower surface of the silicon substrate and a second cylinder space substantially coaxially defined on the first cylindrical space, a diameter of the second cylinder space is greater than a diameter of the first cylinder space.

9. The solar cell of claim 1, wherein the plurality of three-dimensional nano-structures have structures of simple cube, close hexagon, or concentric circle.

10. The solar cell of claim 1, wherein a distance between adjacent three-dimensional nano-structures ranges from about 10 nanometers to about 1000 nanometers.

11. The solar cell of claim 1, wherein the plurality of three-dimensional nano-structures and the silicon substrate are an integrated structure.

12. The solar cell of claim 1, wherein the upper electrode comprises a first part and a second part, the first part is suspended over the doped silicon layer, and the second part is in contact with the doped silicon layer.

13. The solar cell of claim 1, wherein the upper electrode is in contact with the doped silicon layer.

14. A solar cell, comprising: a back electrode, a silicon substrate, a doped silicon layer and an upper electrode which are arranged in that sequence, wherein the silicon substrate comprises a plurality of three-dimensional nano-structures adjacent to the upper electrode, each three-dimensional nano-structure is a stepped structure.

15. A method for making a solar cell, comprising:
providing a silicon substrate having an upper surface, a lower surface, and a plurality of stepped three-dimensional nano-structures located on the upper surface;
attaching a doped silicon layer to the plurality of three-dimensional nano-structures and the upper surface of the silicon substrate between the three-dimensional nano-structures;
applying an upper electrode on at least part of a surface of the doped silicon layer; and
placing a back electrode on the lower surface of the silicon substrate to electrically contact with the silicon substrate.

16. The method of claim 15, wherein the plurality of stepped three-dimensional nano-structures is formed by the following steps of:
providing a silicon plate having the lower surface and a second surface opposite to the lower surface;
forming a mask layer on the second surface of the silicon plate;
etching the second surface of the silicon plate and the mask layer by a reacting atmosphere, to form the plurality of stepped three-dimensional nano-structures; and
removing the mask layer.

17. The method of claim 16, wherein the step of forming the mask layer on the second surface of the silicon substrate further comprises steps of:
preparing a nanosphere solution including a plurality of nanospheres;
forming a monolayer nanosphere solution on the second surface of the silicon plate, wherein the plurality of nanospheres are arranged on the second surface of the silicon plate in form of an array;
and drying the monolayer nanosphere solution absorbed on the second surface of the silicon plate.

18. The method of claim 17, wherein the monolayer nanosphere solution is formed by a Czochralski method or a spinning coating method.

19. The method of claim 16, wherein the step of etching the second surface of the silicon plate and the mask layer by the reacting atmosphere is carried out in a microwave plasma system at Reaction-Ion-Etching mode.

20. The method of claim 16, wherein the mask layer is a continuous film defining a plurality of through holes.
